(19) United States
(12) Patent Application Publication
(10) Pub. No.: US 2013/0306476 A1
(43) Pub. Date: Nov. 21, 2013

(54) NANOWIRE DEVICE FOR MANIPULATING CHARGED MOLECULES

(71) Applicants: Lars Samuelson, Lund (SE); Jonas Tegenfeldt, Lund (SE)

(72) Inventors: Lars Samuelson, Lund (SE); Jonas Tegenfeldt, Lund (SE)

(73) Assignee: QUNANO AB, LUND (SE)

(21) Appl. No.: 13/982,892

(22) PCT Filed: Feb. 1, 2012
(86) PCT No.: PCT/SE12/50098

§ 371 Date: Jul. 31, 2013

(30) Foreign Application Priority Data
Feb. 1, 2011 (SE) 1150068-3

(51) Int. Cl. B81B 1/00

(52) U.S. Cl. CPC B81B 1/00
USPC 204/451; 204/601

(57) ABSTRACT

The invention relates to a nanowire device for manipulation of charged molecules, comprising a tubular nanowire with a through-going channel; a plurality of individually addressable wrap gate electrodes arranged around said tubular nanowire with a spacing between each two adjacent wrap gate electrodes and means for connecting the wrap gate electrodes to a voltage source. The invention further relates to a nanowire system comprising at least one nanowire device, and to a method for manipulating of charged molecules within a through-going channel of a tubular nanowire.

### FIELD OF THE INVENTION

The present invention relates to introduction of molecules into cells, and in particular by using tubular nanowires as introduction devices, in accordance with the preamble of the independent claims.

### BACKGROUND OF THE INVENTION

It is well-known that cancer is a heterogeneous disease and that the tumour of a patient consists of many different cell populations. Thus, very little is known about how cells with different phenotypes react towards chemotherapeutic treatment. This makes it difficult to predict the clinical progression of a tumour and it makes existing treatments suboptimal.

A great challenge in biology is the real-time observation of processes at the single cell level where fundamental processes relevant to life can be observed as well as important insights in the underlying heterogeneity among cells can be gained. Currently lacking in this field is the combination of two abilities: first, to perturb and probe large number of cells individually in real time with minimal cell damage; second, the ability to observe the dynamic response of each individual cell (i.e. without fixing the cell) with ultra-high spatial resolution on the scale of the relevant molecular and structural features of the cell.

The transfer of molecules into the cytosol of single cells is a fundamental challenge in biology. Electroporation and viral vectors are common tools but they suffer from significant drawbacks and limitations such as poor control over which individual cells are transfected and varying transfection efficiency within a group of cells. Electroporation requires the cells to desorb from the substrate and significant time is required for the cells to recover afterwards. Viral vectors require labs with an adequate safety level. Micro and nanoscale needles can be used as an alternative but they too suffer from several drawbacks. Large needles perturb the cells mechanically and must be used at extremely low speeds. Solid nanoscale needles have been used but they can only transfer one single load of molecules into the cell. As disclosed in Meister, A. et al., FluidFM: Combining Atomic Force Microscopy and Nanofluidics in a Universal Liquid Delivery System for Single Cell Applications and Beyond. Nano Letters, 2009. 9(6): p2501-2507, it is known to use an AFM cantilever together with fluidics and a drilled hole in the pyramidal tip. Thereby precise control of injection into one single cell can be reached, but since it is limited to handling one cell at a time it provides inadequate statistics to characterize the full heterogeneity within cell populations.

In “Nanofluidics in hollow nanowires”, Niklas Sköld et al. IOP Science Nanotechnology 21 (2010) 155301, a method for producing free-standing hollow nanowires from GaAs—AlInP core-shell nanowires by selective GaAs etching is disclosed. Hollow nanowires can be used for introduction of materials to and from single cells. Here GaAs—AlInP core-shell nanowires were grown on either GaAs(111)B or GaAs(001) substrates using metal-organic vapor phase epitaxy (MOVPE) at 100 mbar pressure with H2 as the carrier gas. The nanowires were subsequently embedded in a polymer membrane after which the GaAs core was selectively etched away to form hollow nanowires. The inner and outer diameters of the nanotubes are thus defined by the nanowire core diameter and the shell thickness, respectively, and can be chosen almost arbitrarily.

FIG. 1 shows the fabrication steps of the hollow nanowires, which will now be further explained. (a) Prior to growth of the nanowires, the central part of the substrates was thinned down to a thickness of 50 μm, to facilitate the etching of the backside connection to the hollow nanowires at a later stage. Gold-particle assisted growth was then used to produce the nanowires. Size selected aerosols were deposited on the front side of the substrates, which were then placed in an MOVPE reactor cell. The GaAs core was grown using trimethyl gallium (TMG) and arsine (AsH3) at a temperature of 450° C., where kinetic limitations suppress radial growth.

(b) An Al0.5In0.5P shell, lattice-matched to the GaAs core, was grown. The AsH3 was switched off and phosphine (PH3) followed by trimethylaluminum (TMA) were switched on, leading to the growth of a thin AlP spacer. After 2 s, trimethylindium (TMI) was added to the chamber for AlInP shell growth. The precursor molar fractions were 1.5×10⁻² for PH3, 1×10⁻⁵ for TMA and 2×10⁻⁵ for TMI. It should be noted that other shell materials could equally well be used. The AlInP shell can be replaced by an Al2O3 shell (which is more biocompatible), deposited post-growth by atomic layer deposition, without any modifications to the rest of the fabrication steps.
(c) The samples were then removed from the reactor cell and the nanowires were partially embedded in a benzocyclobutene (BCB) film. An adhesion promoter was spun onto the samples immediately followed by the BCB resin, when the rotational speed was 3000 rpm. The BCB was then cured in a N2 atmosphere.
(d) Photoresist was spun onto the samples at 3000 rpm and baked at 120° C. This leaves only the tips of the nanowires sticking out of the resist.
(e) The tips can then be scraped off using a piece of cleanroom tissue in order to access the core for etching.
(f) The backside connection to the hollow nanowires was etched out by placing a drop of H2O2(30%):H2SO4:H20 (8:1:1) solution in the backside dimple. One or a few membranes are thereby formed at the bottom of the dimple.
(g) The cores of the nanowires were subsequently etched out using an H2O:NH3(29.5%):H2O2(30%) (140:3:1) solution. Although the etchant had to diffuse through the nanotubes the etch rate was approximately equal to the etch rate of macroscopic apertures, i.e. 200 nm min-1.
(h) Finally, the photoresist was removed with e.g. Microposit Remover 1165, leaving free-standing hollow nanowires suspended by a BCB membrane.

The hollow nanowires were partially embedded in a polymer film in order to form a nanotube membrane, and electrophoretic transport of T4-phage DNA was demonstrated using epifluorescence microscopy. In the electrophoretic transport, a DC electric field was applied across the device by dipping platinum electrodes in the buffer solution. A bias of 5 V was applied across the membrane.

One crucial function of the nanowires is controlled transport of molecules to and from the cells. It is important to prevent any spontaneous diffusion to avoid depletion of the cytosol.

It is known in the art to provide a system comprising a single wrap gate electrode arranged around the nanotube that is adapted to transport charged molecules. Such a system is known from US2009283751. However, this system is ridden with considerable drawbacks as regards precise control of the transport of charged molecules. More specifically, the system is limited to transporting large number of charged particles dissolved in bulk fluid.

Thus, the object of the invention is to provide an improved system for controlled transport of molecules to and from cells, using hollow nanowires for the transportation.

### SUMMARY OF THE INVENTION

The above-mentioned object is achieved by a nanowire device for manipulation of charged molecules, comprising a tubular nanowire with a through-going channel, a plurality of individually addressable wrap gate electrodes arranged around said tubular nanowire with a spacing between each two adjacent wrap gate electrodes, and means for connecting the wrap gate electrodes to a voltage source.

According to another aspect, the object is achieved by a nanowire system comprising at least one nanowire device, wherein the system further comprising at least one voltage source configured to apply a voltage to said plurality of individually addressable wrap gate electrodes.

According to a further aspect, the object is achieved by a method for manipulating of charged molecules within a through-going channel of a tubular nanowire, comprising:
arranging a plurality of wrap gate electrodes around said tubular nanowire;
connecting the plurality of wrap gate electrodes to a voltage source, and
applying at least one voltage to said plurality of individually addressable wrap gate electrodes from said voltage source.

The nanowire-based injection system according to the present invention renders possible accurate control of the amount of active material injected into each cell. In particular, the individually addressable wrap gates enable the establishment of a spatially and temporally non-uniform electrical potential inside the hollow nanowire. More specifically, by applying a gate voltage on the wrap gate electrode the corresponding portion of the interior of the tubular nanowire becomes a potential well, i.e. a region of local energy minimum, for the species of the corresponding polarity. Said potential well collects and confines charged species of the selected polarities, such as ions and charged molecules. In this context, applying mutually opposite potentials to two neighboring wrap gates allows to trap species of both polarities. The position of the potential well may be spatially shifted by means of a suitable activation sequence for the individual wrap gates. Thus, the potential well travels along the length of the nanowire in the direction of the outlet of the nanowire. As for the charged species confined within the potential well, when the voltage is applied, these species are additionally energized. Therefore, they start to drift out of their current potential well and diffuse into the interior of the tubular nanowire. Subsequently, they are influenced by another, suitably placed and designed potential well, i.e. the potential well being positioned closer to the outlet of the nanowire and having even lower minimum energy than the one they just drifted out of, and migrate into it. Consequently, they move in the same direction as the sequence of potential wells created by the applied voltage. In this context, movement of the charged particles in the interior of the tubular nanowire may be analogised with propagation of the travelling wave. Thus, by suitably manipulating voltage of each wrap gate electrode, it can be achieved that the charged species are transported from the inlet of the tubular nanowire and all the way to, or close to, its outlet where delivery of said species takes place. In this context, the nanowire-based injection system of the present invention renders possible accurate control of the amount of active material injected down to only a few or, for larger molecules, even single molecules. From the above it may also be inferred that a set-up comprising a single wrap gate cannot create the positional shift of the potential well and the trapped charge along the length of the hollow nanowire.

Moreover, present invention offers unprecedented control of transport and delivery processes. In particular, the invention makes it possible to inject a sequence of different molecules into the cell or to repeatedly inject a given amount of molecules, in both cases with high temporal resolution.

In addition, present invention makes it possible to individually connect the cytosol of each cell through a nanowire device to a multiplexed fluidics network for simultaneous biochemical stimulation and real-time analysis of the cytoplasm of the cell, including biochemical reactions controlled by organelles, as well as the membrane surrounding cells.

Furthermore, it is possible to have arrays of single cells connected to a nanowire system with nanowire devices.

Applications of the invention in the field of systems biology are especially interesting, but other fields of application, such as controlled delivery of drugs in the context of cancer drug screening, are conceivable.

Preferred embodiments are set forth in the dependent claims and in the detailed description.

### SHORT DESCRIPTION OF THE APPENDED DRAWINGS

Below the invention will be described in detail with reference to the appended Figs., of which:

FIG. 1a-1h illustrates AlInP tubular nanowire fabrication steps.

FIG. 2 shows a nanowire device according to one embodiment of the invention.

FIG. 3 shows a tubular nanowire (here named hollow nanowire) according to one embodiment of the invention, in connection with a cell and a membrane.

FIG. 4 shows a system comprising a nanowire device according to one embodiment of the invention.

FIG. 5 shows a nanowire device according to another embodiment of the invention.

FIG. 6 illustrates an example of a mode of operation of a nanowire device with several gates.

FIG. 7 illustrates an example of a mode of bipolar operation of the nanowire.

FIG. 8 illustrates two pairs of counter directed diodes.

FIG. 9 illustrates two pairs of counter directed diodes implemented as three gates.

FIG. 10 illustrates the use of a flexible channel.

### DETAILED DESCRIPTION OF PREFERRED EMBODIMENTS OF THE INVENTION

The embodiments of the present invention are based on nanostructures including so-called nanowires. For the purpose of this application, nanowires are to be interpreted as having nanometre dimensions in their width and diameter and typically having an elongated shape that provides a one-dimensional nature. Such structures are commonly also referred to as nanowhiskers, nanorods, nanotubes, one-dimensional nanoelements, etc. The basic process of nanowire formation on substrates by particle assisted growth or the so-called VLS (vapour-liquid-solid) mechanism described in U.S. Pat. No. 7,335,908, as well as different types of Chemical Beam Epitaxy and Vapour Phase Epitaxy methods, are well known. However, the present invention is limited to neither such nanowires nor the VLS process. Other suitable methods for growing nanowires are known in the art and is for example shown in international application No. WO 2007/104781. From this it follows that nanowires may be grown without the use of a particle as a catalyst.

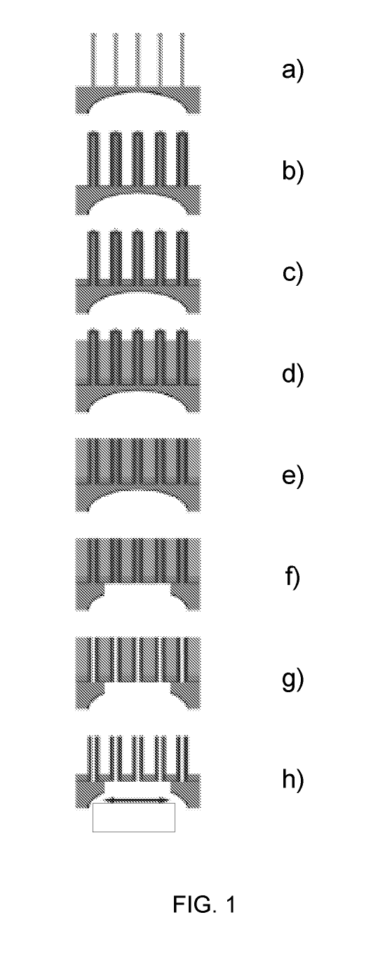

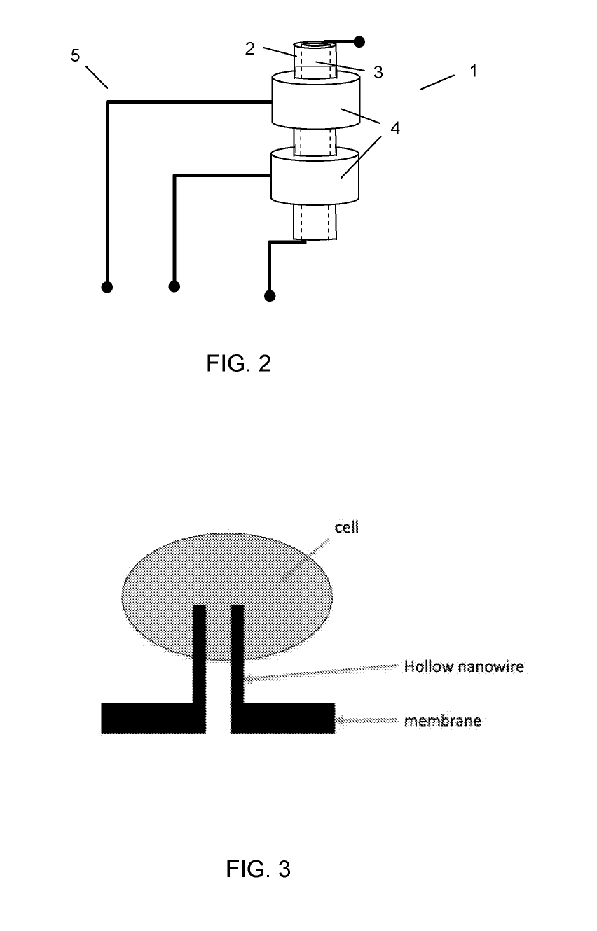

Referring to FIG. 2, a nanowire device 1 according to one embodiment of the present invention is shown, and will now be further explained. The nanowire device 1 is used for manipulation of charged molecules, and comprises a tubular nanowire 2 with a through-going channel 3. The tubular nanowire 2 is defined as having a lengthwise extension and any cross-section, and a through-going channel 3 along the lengthwise extension of the tubular nanowire 2. This kind of nanowire 2 is also referred to as a hollow nanowire, which method of fabrication has been previously explained. The explained method of fabrication as illustrated in FIG. 1a-1h shall not be seen as limiting, and there are many other possible alternatives in the fabrication method with respect to choice of materials in the different layers and actual process steps.

The nanowire may comprise a core and at least a first shell layer. Before the nanowire is etched to create a tubular nanowire 2 with a channel, it comprises a core. The core can be made out of basically any semiconductor, such as group-IV materials, like Si and Ge, any III-V material, like GaAs, InP etc. The nanowire is also provided with a shell, and the shell can be of the same type as the core, preferably choosing a material with etching contrast allowing selective etching of the core. The shell may instead be made from a very different material, such as SiO2 or Al2O3, making the surface of the tubular nanowires more bio-compatible. Also Si3N4 and other dielectric materials are possible, and polymers could be useful in certain cases. Essentially the shell can be made in any material that has the required mechanical, chemical, electrical and possibly optical properties necessary.

Mechanical properties—it should be strong enough not to break during normal use such as during the insertion into the cell.

Chemical properties—it should not be toxic to the cell, and it should be compatible with the desired surface chemical modifications that need to be done.

Electrical properties—insulator for a purely capacitive coupling that is desired for the gating, alternatively semiconducting for integrated PN junctions for detection or LEDs etc.

Optical properties—the material can be transparent, unable to autofluoresce and/or have integrated quantum dots.

The outer diameter of the tubular nanowire 2 may be in the rage from 10 nm to 1000 nm, preferably between 200 nm to 1000 nm. The inner diameter of the tubular nanowire 2 can be made, typically, in the range 5-200 nm, and preferably 50-200 nm.

The exterior surface of the tubular nanowire 2 might comprise a supported lipid bilayer, to make insertion into a cell easier. Any surface coating may be applied to the interior of the tubular nanowire, limited though by the chemical affinities of each material chosen for the tubular nanowire 2. One common example of coating is lipid bilayers. These are proven excellent for rendering the surfaces inert to non-specific passivation.

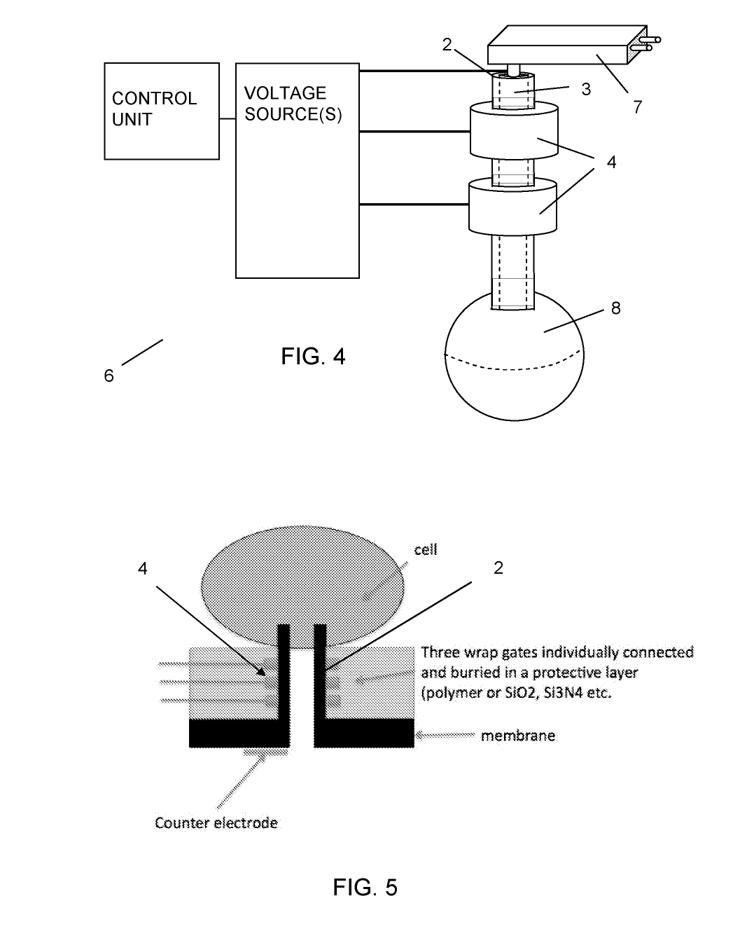

Nanowire devices 1 can be produced from free-standing tubular nanowires, a method that allows easy control of the nanowire dimensions and position in the system. The tubular nanowires are, according to one embodiment, subsequently partially incorporated into a polymer membrane. As the tubular nanowire tips are left free they can also be used as needles. The channels 3 of the nanowires 2 are according to one embodiment in contact with both sides of a membrane to which the tubular nanowires 2 may be attached as illustrated in FIG. 3, making it possible to interface biological cells 8 using the needles on one side and to connect to a microfluidic network, also referred to as supply network 7 and shown in FIG. 4, on the other side. This configuration enables not only biomolecular detection but also injection into living cells 8 in a similar fashion as arrays of hollow microcapillaries but with minimal damage to the cells as the needle diameter. Thus, the nanowire tip diameter is, according to one embodiment, only a few hundred nanometers.

According to one embodiment, the nanowire device 1 comprises a plurality of individually addressable wrap gate electrodes 4 arranged around the tubular nanowire 2 with a spacing between each wrap gate electrode 3.

Wrap gates have been developed to control the vertical current in a nanowire FET (Field-Effect Transistor) and is a cylindrical alternative to planar gates as used in traditional FETs. The length of a wrap gate electrode 4 can be varied from about 25 nm up to a couple of μm in length. The wrap gate electrode 4 encloses at least a portion of the tubular nanowire 2 with a dielectric material (not shown) in-between (also referred to as a shell). Examples of dielectric materials are for example SiO2 and Si3N4, as explained before.

Referring to FIG. 2, a first wrap gate electrode 4 extends along a portion of the tubular nanowire 2 and encloses a first lengthwise region of the nanowire 2 with a dielectric material in-between. A second wrap gate electrode 4 extends along another portion of the nanowire 2 and encloses a second lengthwise region of the nanowire 2 with a dielectric material in-between. The tubular nanowire 2 forms a transport channel 3, in which a fluid with charged molecules can be transported in either direction. In this embodiment, a top contact is positioned so that it is in electrical contact with the fluid at one end portion of the tubular nanowire 2 when the nanowire device is in use, and a bottom contact is positioned at the other end of the nanowire 2 so that it is in electrical contact with the fluid in the other end of the nanowire 2, as illustrated in the Fig. The first and second wrap gate electrodes 4 are separately addressable. The nanowire device 1 may comprise further separately addressable wrap gate electrodes 4.

The electrodes at both ends of the nanowire 2 can be used for electrophoresis or dielectrophoresis as a complement to the wrap-gate induced transport.

The wrap gate electrodes 4 may be electrically insulated from the nanowire 2 interior by an oxide wall of the nanowire 2. Each level of gates 4 can be individually electrically controlled, and the wrapping geometry, combined with the wires' 2 very small dimensions, will provide strong capacitive, electrostatic control of the nanowire 2 interior. Capacitive coupling means that the dielectric material in immediate proximity of the electrodes will polarize. No DC current will flow. For example, if a negative voltage is applied to the electrode, the surface charge of the inside of the channel 3 of the tubular nanowire 2 will be more negative. If it is positive, the surface charge will be more positive.

Another embodiment of a nanowire device is shown in FIG. 5. A tubular nanowire 2 is here illustrated surrounded by three wrap gate electrodes 4, but the number of wrap gates 4 may of course be less or more to achieve a desired effect. The tubular nanowire 2 is in this embodiment defined to have a base portion, a lower portion, an upper portion and a top portion. In the Fig., a membrane is positioned at the base portion of the nanowire 2, and a cell 8 is positioned at the other end of the nanowire 2, i.e. at the top portion. The cell 8 is here shown as being pierced by the tubular nanowire 2. The wrap gates 4 are preferably individually connected to a voltage source for applying a voltage to the wrap gates 4, and buried in a protective layer of e.g. polymer, SiO2 or Si3N4. In FIG. 5, the counter electrode may be defined at the one end of the tubular nanowire 2, in the Fig. the counter electrode is positioned close to the base portion in connection with the membrane. The wrap gates are according to one embodiment positioned in the lower part of the tubular nanowire, thus closer to the base portion than to the top portion and the cell. When voltage is applied to the gates 4, they will then pump the desired molecules roughly halfway up along the channel of the nanowire 2 in the direction of the cell. Diffusion will then ensure that the desired molecules reach the final destination in the cell. This positioning of the wrap gates 4 is also possible for the other embodiments according to the invention as explained herein.

Each wrap gate 4 combined with a connection to a voltage source can be made as follows: A protective dielectric (SiO2 etc.) is deposited; subsequently a wrap gate 4 together with a connecting metal line is defined; the process is repeated until the desired number of wrap gates 4 are made.

In FIG. 4, a nanowire system 6 according to the invention is shown, comprising at least one nanowire device 1. The system 5 further comprises at least one voltage source configured to apply a voltage to said plurality of wrap gate electrodes 4. The applied voltage is, according to one embodiment, in the range of 1 to 100 V. The required gate voltages will depend on the design particularities of the nanowire device 2 and the buffer composition, primarily the buffer ionic strength. According to one embodiment, if a thin gate is used, a lower voltage is needed. The term “thin” should here be understood as a specification of the thickness of a gate 4 in the vertical direction of the tubular nanowire 2.

The wrap gates 4 of FIG. 4 are preferably connected directly of indirectly to a control unit via one or several voltage sources. The nanowire system 6 then comprises a control unit, and the control unit may be conFig.d to control the at least one voltage source to apply voltage(s) to said plurality of wrap gate electrodes 4 according to a predetermined schedule. Thus, it is possible to individually electrically control each gate 4, by individually addressing the respective wrap gate 4. According to one embodiment, the at least one predetermined schedule comprises instructions for a sequential activation of the wrap gate electrodes 4 to create a pumping action of the tubular nanowire 2 in the form of a travelling wave to bring charged molecules along the channel 3 of the tubular nanowire 2. The control unit preferably comprises necessary memory and processing means for executing said instructions and predetermined schedules. The control unit may also comprise an interface allowing the user to interact and control said system.

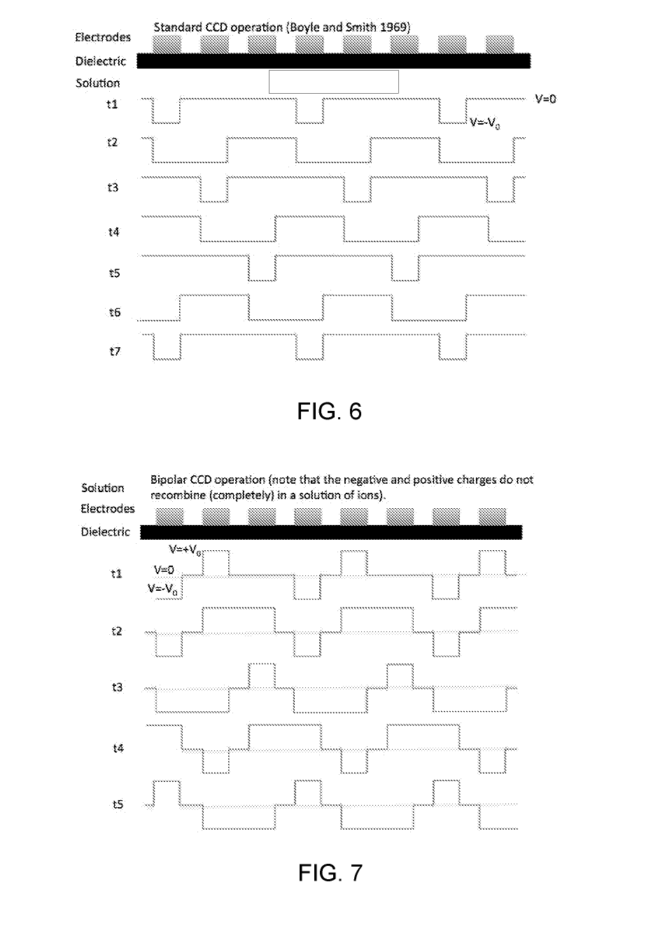

When the gates 4 are addressed, and voltages are applied to the wrap gate(s) 4, a pumping action of the tubular nanowire 2 is achieved, and charged molecules inside the channel 3 of the nanowire 2 are brought in motion in a desired direction of the channel in the lengthwise direction of the nanowire 2. The pumping action relies on a travelling wave. The manipulation of charged molecules is thus achieved by an electrostatic driving force created inside the channel 3 when voltage is applied to the wrap gate electrode(s) 4. The tubular nanowire 2 has an inner surface, thus the surface of the channel 3, and the surface charge of the inner surface is modulated by the voltage applied with the wrap gate(s) 4. According to one embodiment, a denser set of gates 4 provide faster and more efficient pumping. The gates 4 do not all have to be controlled independently. Some gates 4 may be jointly controlled in order to create a specific effect, such as a more powerful pumping. FIG. 6 illustrates a mode of operation with multiple gates.

Material in the form of charged molecules is thus inserted into the tubular nanowires 2 using the pumping action of the wrap gate 4 due to the travelling wave as visualized in FIGS. 6 and 7. According to one embodiment, voltages are applied to the gates such that two travelling waves are formed with interchanging waves. The travelling wave does not need to extend along the entire length of the nanowire 2. The wrap gates 4 can be defined within buried layers (see FIG. 5) allowing diffusion to transport the molecules the last part of the nanowire 2. This approach may render the technique somewhat slower, but it may make the fabrication of the structure easier. To create the possibility of transporting exactly one molecule at a time, the molecules could be coupled to larger carriers that would in turn be degraded within the cell, thereby releasing the molecule of interest.

The gating as well as the kinetics is different for small molecules each with little charge and for larger molecules which typically have more charge. The gating thus has to be adjusted for each such case. Highly charged molecules need less applied voltage than molecules with less charge. It is also important to consider that some molecules are negatively and some positively charged, and also the flow of counterions. Small molecules have larger diffusion coefficient which makes their transport (and escape if no valve or pump is active) faster. Thus, the system 6 has to be adapted after the kind of molecules that the nanowire device 1 is intended to pump or act as valve for. The lowest rate of pumping is single molecules one by one. It is also possible to pump higher rates and concentrations of molecules.

According to a further embodiment, the method comprises: arranging a plurality of wrap gate electrodes 4 around said tubular nanowire 2; connecting said plurality of wrap gate electrodes 4 to at least one voltage source; applying voltages to said wrap gate electrodes 4 according to a predetermined schedule in order to create a sequential activation of the wrap gate electrodes 4 to create a pumping action of the tubular nanowire 2 in the form of a travelling wave to bring charged molecules along the channel 3 of the tubular nanowire 2.

According to a further embodiment, the invention comprises a method for manipulating charged molecules within a through-going channel 3 of a tubular nanowire 2, comprising: providing a nanowire system according to the invention; providing at least one charged molecule to the interior of the channel 3 of the tubular nanowire 2 of the system 5; and applying at least one voltage to the wrap gate electrodes 4 for generating a travelling wave in the nanowire 2 whereby said charged molecule(s) are moved along the channel 3. Thus, a pumping action of the nanowire device 1 is achieved.

If the nanowire device 1 comprises only one wrap gate 4, the function of the device 1 will be that of a valve. With this kind of nanowire device 1, very fast valves acting on charged molecules can be realized. With the gate 4 in an open condition, diffusion can occur, but there will not be an electrostatic driving force in this case, the way it is with the multiple gates. It can be made to attract or repel charged entities and thereby hinder direct transport from one side to the other of the tubular nanowire 2. Furthermore it could be used to gate a feature that in turn provides a blocking function. According to one embodiment, two counter-directed ionic diodes can be used as a valve. In this embodiment two gates 4 are needed.

According to one embodiment, a mechanical plug can be made using electropolymerization. There are polymers that can change their conformation so that they switch from a compact state to an expanded state and back depending on external stimulus (for example light, ionic strength, pH, change in temperature). Such a polymer could be used as a plug. For example, if they are attached to the inside surface of tubular nanowire 2, the local pH can be controlled using a setup with external gates 4. In this way the transport through the channel 3 can be controlled.

According to one embodiment, control of the transport through the tubular nanowire may be achieved using a series of three gates 4 as shown in FIG. 5, which can be operated similarly to a charge-coupled device (or a peristaltic pump), deterministically pushing a small volume (order of 10-18 litres) of small molecules along the channel 3 of the nanowire 2. For example, with a gate spacing of 100 nm, it is according to one embodiment possible to controllably manipulate single oligonucleotides with few hundred by or less.

In a different mode of operation, smaller voltages can be used to realize a ratchet mechanism that rectifies the molecules' thermal motion to achieve controlled transport. A ratchet mechanism is similar to the principle used in Charge-Coupled Devices (CCDs), where three gates enable the trapping of a certain amount of charge (electrons), and where it is possible to shift this pocket of electrons step-by-step under the gates by sequentially shifting the attractive potential step-by-step under these gates. In the CCD-case one even makes many such unit-cells with three such gates. In the present case the tubular nanowire 2 is preferably surrounded by three gates 4 to attract single or multiple charged molecules and to be able to controllably shift these molecules along the channel 3 of the tubular nanowire 2. Once the molecules have been attracted from one side of the tubular nanowire 2 and passed over to the opposite end, the molecules will diffuse out from that point. Essentially, a travelling wave is created that traps the desired charged molecules. If the wave packet is a dip, then positively charged molecules will be transported, if it is a peak it will transport negatively charged molecules. If a peak and a dip are combined, all charged molecules will be transported by the travelling wave, in the direction of the travelling wave. This is visualized in FIG. 7.

One important aspect is to make sure that counterions inside the channel 3 of the nanowire 2 are free to flow as well, so that the net charge change is zero.

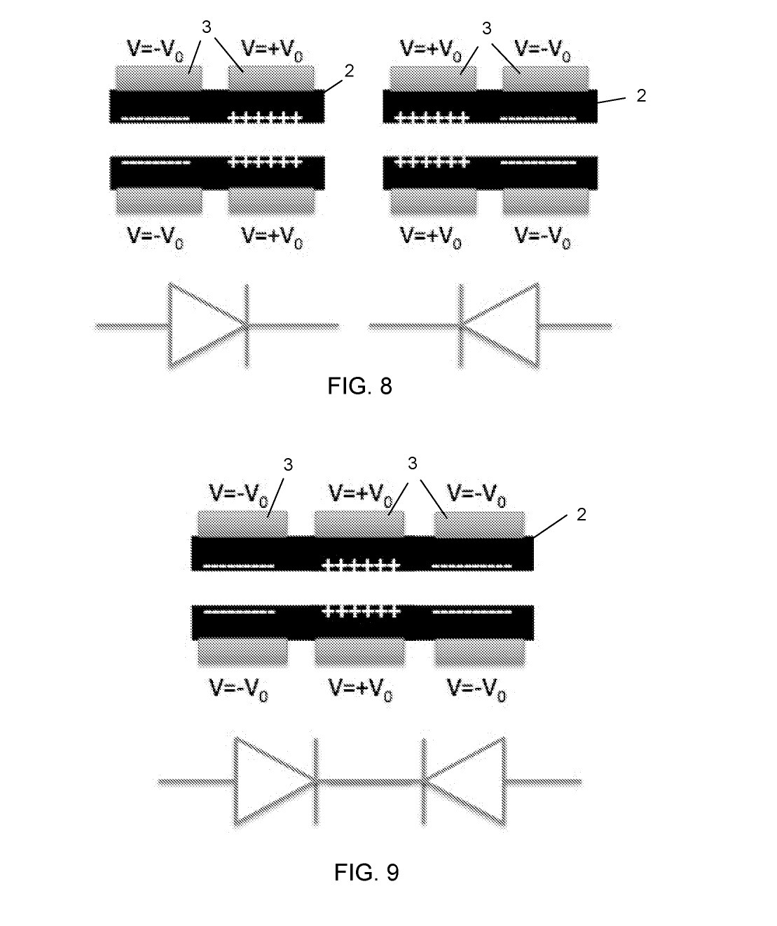

Static potential staircase creates a diode. According to one embodiment, the nanowire device 2 comprises diodes that are counter-directed to create a blocking valve. It is known from the literature that with a channel that has one part with relatively positive surface charge and one part with relatively negative surface, the transport of ionic species is rectified. It thus acts as a diode for ions. Interconnecting two such diodes such that they point in two different directions will thus block the flow of both positive and negative ions. Such a pair of diodes, illustrated in FIG. 7, can be realized with three gates 4 along the tubular nanowire 2 as shown in FIG. 8, the central gate with a positive voltage and the outer gates with a negative voltage or the converse voltage. With two gates a single diode is the result. Depending on the choice of voltages the direction of the ionic current can be controlled.

The tubular nanowire 2 is inserted into a cell 8 spontaneously or using a flexible channel. Some cells 8 spontaneously interact with the tubular nanowire 2. The cell 8 can be allowed to grow on arrays of nanowires or a single nanowire on a surface and they will then spontaneously try to engulf the nanowires 2. One example of such a cell 8 is a macrophage cell.

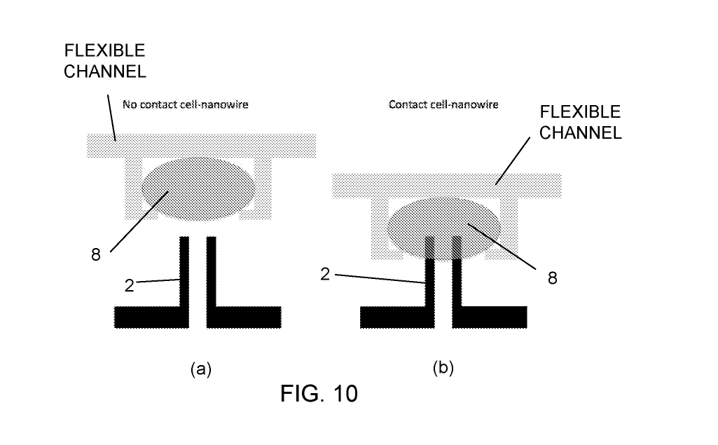

Using a flexible channel as shown in FIG. 10, the roof of the channel can be pushed down at the cell 8, thereby applying an extra force to help the nanowire 2 penetrate the cell 8. This is especially important for bacteria where the nanowire 2 may have difficulty to penetrate the wall of the cell. It can also enable control of when and where the cells are connected. To create a good seal with the cell membrane a hydrophobic ring can be created around the nanowire 2. According to one embodiment, the cells 8 are trapped in a channel as shown in FIG. 10a, and then the channel is deformed with the cells 10 such that the cells 10 are brought into contact with the nanowires as shown in FIG. 10b. The flexible channel is according to one embodiment defined in silicone rubber or any other elastomer. It is designed with structures that capture the cells 8 so that they are held in place in close proximity but not in contact with a nanowire 2. By deforming the channel, for example by applying a pressure from the top as shown in FIG. 10, the cell 8 can be brought in close proximity of the nanowire 2 and eventually into contact with the nanowire 2 so that the nanowire 2 connects to the interior of the cell 8.

The tubular nanowires 2 are according to one embodiment grown monolithically on a semiconductor chip. On this chip it is also possible to produce a supply structure 7 based on micro-/nanofluidics and comprising containers and transport tubes, to convey materials to and from the nanowire devices 2. An array of tubular nanowires 2 can be created on said chip, such that multiple cells 8 can be connected and each cell 8 can be independently perturbed or probed. The tubular nanowires 2 may according to one embodiment be integrated with a MEMS system that provides a movement of the nanowires 2 so that they could be moved relative to a cell 8 that is fixed in space. According to one embodiment, the nanowire system 5 comprises a supply network 7 for molecules to be delivered to the nanowire device(s) 1, wherein said nanowire device(s) is/are connected to said supply network. Fluidics structures can be defined to position cells 8 in regular arrays. The cells 8 can be pushed down to make contact with the respective tubular nanowire 2 in a chip design. This makes it possible to actively control exactly when the cell 8 is connected with the tubular nanowire 2, further minimizing any mechanical perturbation to the cell 8. Furthermore, the chemical environment around the cells 8 is controlled temporally and spatially using well-established schemes to define spatial concentration gradients. To allow for a complex range of chemical treatments to the cells 8, an advanced highly integrated supply network 7 of channels can be defined on the other side of the tubular nanowires 2. Using a multilayer soft lithography approach a microfluidic multiplexer is the result so that a large number of different biochemicals or concentrations of biochemicals can be combined individually to the cells 8. To ensure a tight seal between the nanowire 2 and the membrane of the cell 8, the nanowire 2 can be provided with a ring-shaped hydrophobic surface treatment.

Transport of a known number of molecules is crucial in systems biology. If the molecules of interest are associated with carriers that can be moved one by one (or detected one by one) such as a vesicle, it is possible to precisely transport a known number of molecules into each single cell.

The present invention is not limited to the above-described preferred embodiments. Various alternatives, modifications and equivalents may be used. Therefore, the above embodiments should not be taken as limiting the scope of the invention, which is defined by the appending claims.

1. A nanowire device for manipulation of charged molecules comprising:
a tubular nanowire with a through-going channel;
a plurality of individually addressable wrap gate electrodes arranged around said tubular nanowire with a spacing between each two adjacent wrap gate electrodes; and
a connector connecting each wrap gate electrode to a voltage source.

2. A nanowire device according to claim 1, wherein said manipulation of charged molecules is achieved by an electrostatic driving force created inside said channel when voltage is applied to plurality of individually addressable wrap gate electrodes.

3. A nanowire system comprising at least one nanowire device according to claim 1, the system further comprising at least one voltage source configured to apply a voltage to said plurality of individually addressable wrap gate electrodes.

4. A nanowire system according to claim 3, comprising a control unit configured to control said at least one voltage source to apply voltage(s) to said plurality of individually addressable wrap gate electrodes according to a predeteremined schedule.

5. A nanowire system according to claim 1, wherein said at least one predetermined schedule comprises rules for a sequential activation of the wrap gate electrodes to create a pumping action of the tubular nanowire in the form of a travelling wave to bring charged molecules along the channel of the tubular nanowire.

6. A system according to claim 3, comprising a supply network for molecules to be delivered to said at least one nanowire device, wherein said at least one nanowire device is connected to said supply network.

7. A method for manipulating of charged molecules within a through-going channel of tubular nanowire, comprising:
providing a plurality of wrap gate electrodes located around said tubular nanowire
wherein said plurality of wrap gate electrodes are connected to at least one voltage source;
applying voltages to said wrap gate electrodes according to a predetermined schedule in order to create a sequential activation of the wrap gate electrodes to create a pumping action in the tubular nanowire in the form of a travelling wave to bring charged molecules along the channel of the tubular nanowire.

8. A method for manipulating charged molecules within a through-going channel of a tubular nanowire, comprising:
providing a system of claim 3,
providing at least one charged molecule to the interior of the channel of the tubular nanowire of said system;
applying at least one voltage to the wrap gate electrodes for generating a travelling wave in the nanowire whereby said charged molecule(s) are moved along the channel.
